(19) United States
(12) Patent Application Publication
(10) Pub. No.: US 2009/0045770 A1
(43) Pub. Date: Feb. 19, 2009

(54) HEADGEAR ASSEMBLY CAPABLE OF COLLECTING SOLAR POWER

(75) Inventor: Wen-Chang LIN, Kaohsiung Hsien (TW)

Correspondence Address: SHERIDAN ROSS PC, 1560 BROADWAY, SUITE 1200, DENVER, CO, 80202, US

(73) Assignee: YU CHUAN TECHNOLOGY ENTERPRISE CO., LTD., Kaohsiung Hsien (TW)

(21) Appl. No.: 11/838,020

(22) Filed: Aug. 13, 2007

(51) Int. Cl. H02J 7/00; H01L 31/042

(52) U.S. Cl. 320/101

(57) ABSTRACT

A headgear assembly includes a solar power collecting unit mounted on a headgear member for converting solar power into electrical energy, and a power supplying unit having a rechargeable battery set disposed in a housing, connected electrically and wiredly to the solar power collecting unit so as to be charged by the electrical energy therefrom, and a power switch mounted on the housing for controlling electrical connection between a power output port on the housing and the rechargeable battery set so as to permit supply of electrical power from the rechargeable battery set to a load connected electrically to the power output port when in an ON state.

### BACKGROUND OF THE INVENTION

1. Field of the Invention

The invention relates to a headgear, more particularly to a headgear assembly capable of collecting solar power.

2. Description of the Related Art

FIG. 1 illustrates a conventional portable power supply device 1 that includes a casing body 11 configured with two battery-receiving grooves 111 for receiving respectively two rechargeable batteries 10 that are connected electrically in series by a set of electrical contacts 131, 132, 133, 134, a cover body 12 mounted detachably on the casing body 11, a power output port 14 mounted on the casing body 11, a power input port 15 mounted on the casing body 11 and connected electrically to the rechargeable batteries 10, and a power switch 16 mounted on the casing body 11 for controlling electrical connection between the rechargeable batteries 10 and the power output port 14.

The power switch 16 is operable between an OFF state, where the rechargeable batteries 10 are disconnected electrically from the power output port 14, and an ON state, where the rechargeable batteries 10 are connected electrically to the power output port 14 such that electrical power from the rechargeable batteries 10 can be supplied to a load, which is an electronic device, such as a mobile phone, a lighting device, etc. However, when the electrical power stored in the rechargeable batteries 10 is exhausted, it is required to replace the batteries 10 or charge the rechargeable batteries 10 using electrical energy from an external power source (not shown) via the power input port 15, thereby resulting in inconvenience during use.

### SUMMARY OF THE INVENTION

Therefore, the object of the present invention is to provide a headgear assembly that can collect solar power and that can supply electrical power to a load.

According to the present invention, a headgear assembly comprises:

a headgear member adapted to be worn by a user;

a solar power collecting unit mounted on the headgear member and adapted to convert solar power into electrical energy; and

a power supplying unit including

a housing configured with a battery-receiving space,

a rechargeable battery set disposed in the battery-receiving space in the housing and connected electrically and wiredly to the solar power collecting unit such that the electrical energy from the solar power collecting unit is used to charge the rechargeable battery set,

a power output port mounted on the housing and adapted to be connected electrically to a load, and

a power switch mounted on the housing, connected electrically between the rechargeable battery set and the power output port, and operable so as to switch between an OFF state, where the rechargeable battery set is disconnected electrically from the power output port, and an ON state, where the rechargeable battery set is connected electrically to the power output port such that electrical power from the rechargeable battery set is supplied to the load via the power output port.

### BRIEF DESCRIPTION OF THE DRAWINGS

Other features and advantages of the present invention will become apparent in the following detailed description of the preferred embodiments with reference to the accompanying drawings, of which:

FIG. 1 is a partly exploded perspective view of a conventional power supply device;

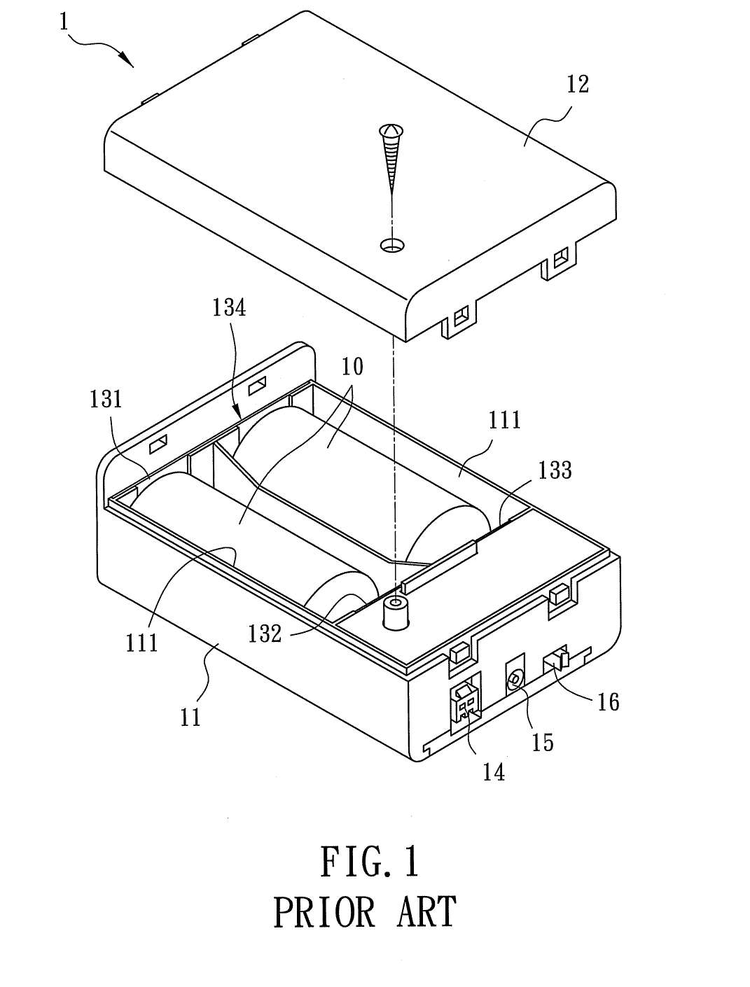

FIG. 2 is a partly exploded perspective view showing the first preferred embodiment of a headgear assembly according to the present invention;

FIG. 3 is a schematic circuit block diagram showing the preferred embodiment;

FIG. 4 is a perspective view showing a power supplying unit of the first preferred embodiment;

FIG. 5 is a perspective view showing the first preferred embodiment when in a state of use;

FIG. 6 is a perspective view showing the first preferred embodiment when in another state of use;

FIG. 7 is a perspective view showing the second preferred embodiment of a headgear assembly according to the present invention; and

FIG. 8 is a perspective view showing the third preferred embodiment of a headgear assembly according to the present invention.

### DETAILED DESCRIPTION OF THE PREFERRED EMBODIMENTS

Before the present invention is described in greater detail, it should be noted that like elements are denoted by the same reference numerals throughout the disclosure.

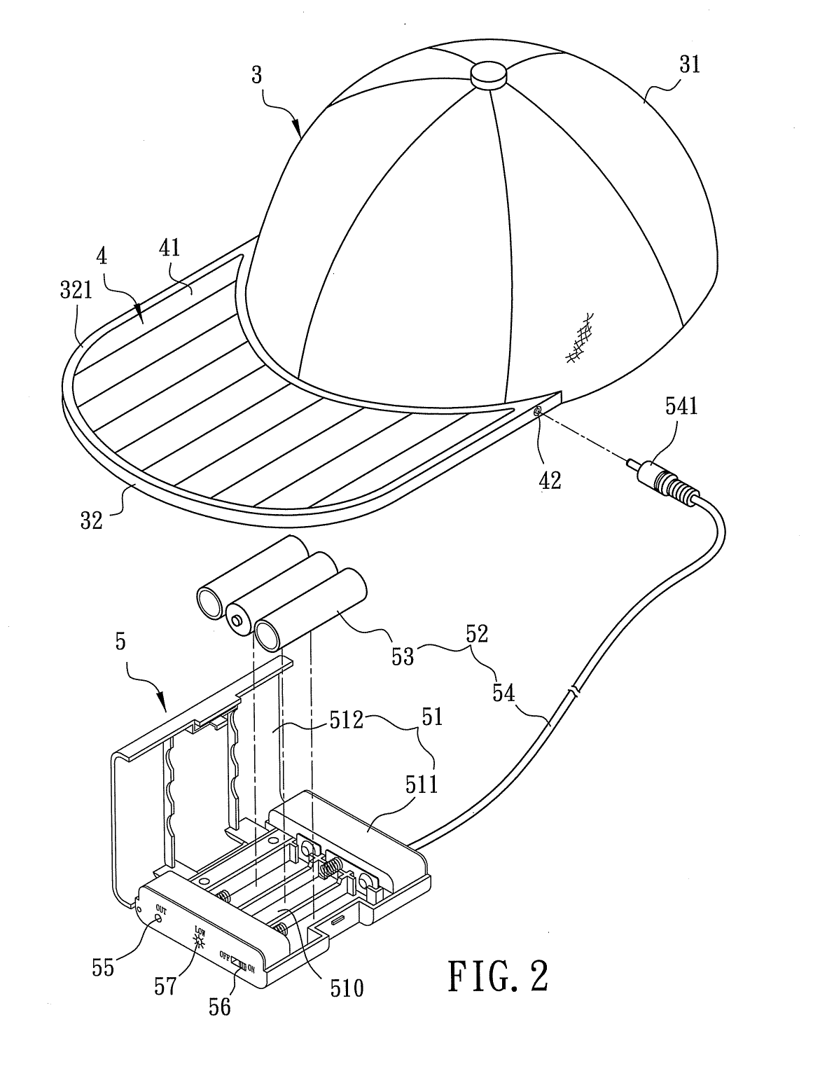

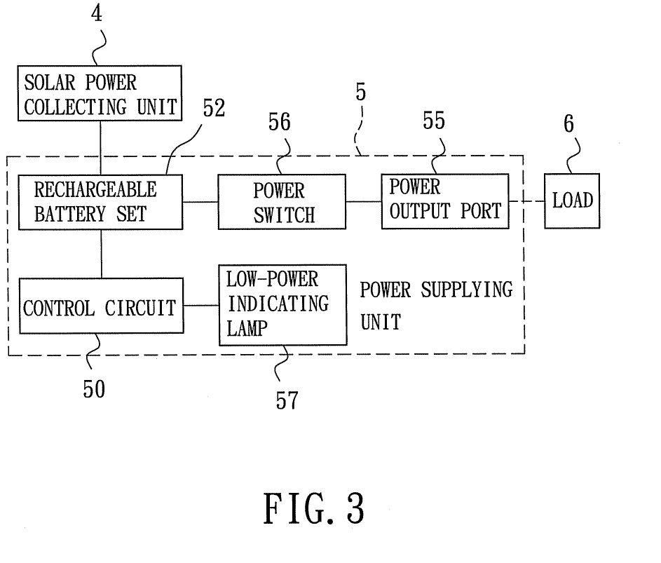

Referring to FIGS. 2 and 3, the first preferred embodiment of a headgear assembly according to the present invention is shown to include a headgear member 3, a solar power collecting unit 4, and a power supplying unit 5.

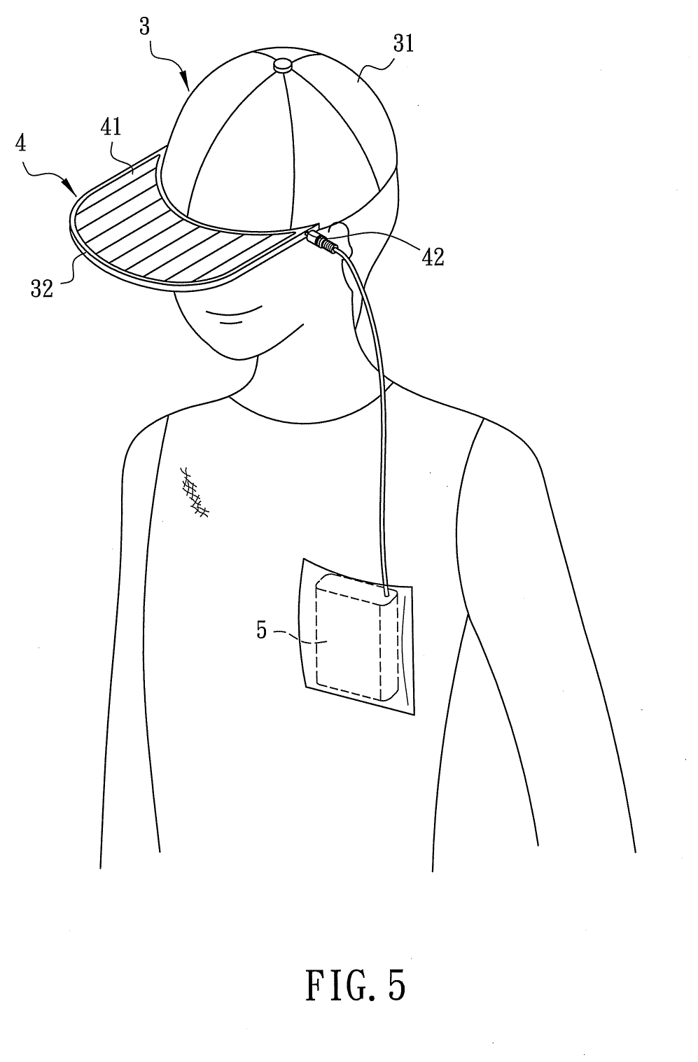

In this embodiment, the headgear member 3 is in a form of a cap that includes a cap body 31 adapted to be worn by a user (see FIG. 5), and a visor 32 connected to and extending outwardly from a periphery of the cap body 31.

The solar power collecting unit 4 is mounted on the headgear member 3, and is adapted to convert solar power into electrical energy. In this embodiment, the solar power collecting unit 4 is mounted on a top surface 321 of the visor 32 of the headgear member 3, and includes a solar power collecting plate 41, and a connecting port 42 connected electrically to the solar power collecting plate 41.

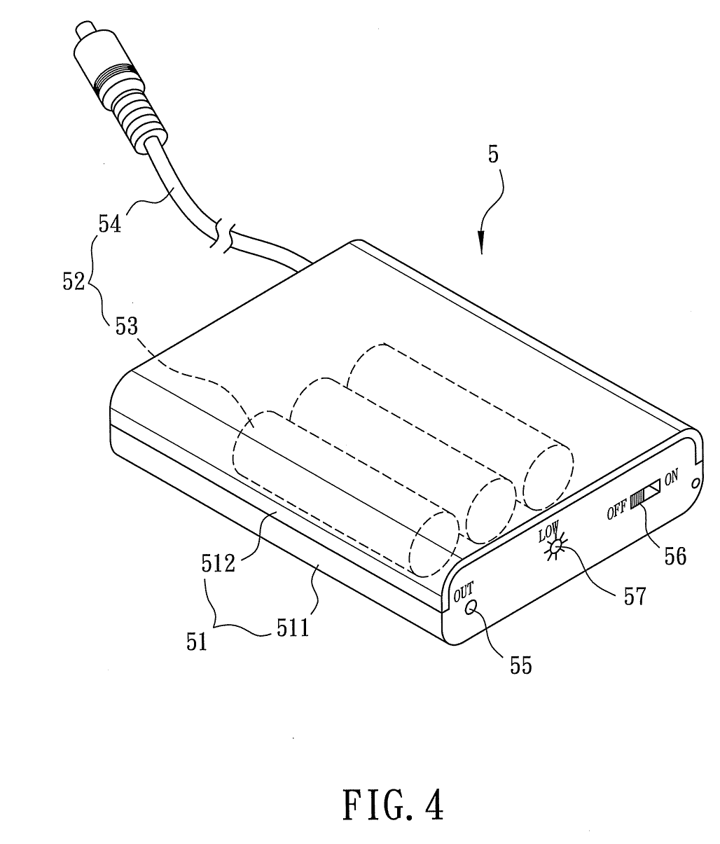

Referring further to FIG. 4, the power supplying unit 5 includes a housing 51, a rechargeable battery set 52, a power output port 55, a power switch 56, a control circuit 50, and a low-power indicating lamp 57.

The housing 51 has a base body 511 configured with a battery-receiving space 510, and a cover body 512 for covering the base body 511.

The rechargeable battery set 52 is disposed in the housing 51, and is connected electrically and wiredly to the solar power collecting unit 4 such that the electrical energy from the solar power collecting unit 4 is used to charge the rechargeable battery set 52. In this embodiment, the rechargeable battery set 52 includes three batteries 53 connected in series and disposed in the battery-receiving space 510 in the base body 511 of the housing 51, and a cable unit 54 connected electrically to the batteries 53 and having a free end 541 that extends outwardly of the housing 51 and that is connected electrically and separably to the solar power collecting plate 41 via the connecting port 42. In this embodiment, the batteries 53 are lithium batteries. In other embodiments, the batteries 53 can be selected from the group consisting of nickel-hydrogen batteries, nickel-cadmium batteries and carbon-hydrogen batteries.

The power output port 55 is mounted on the base body 511 of the housing 51, and is adapted to be connected electrically to a load 6 (see FIG. 3), such as a mobile phone.

The power switch 56 is mounted on the base body 511 of the housing 51, is connected electrically between the rechargeable battery set 52 and the power output port 55, and is operable so as to switch between an OFF state, where the rechargeable battery set 52 is disconnected electrically from the power output port 55, and an ON state, where the rechargeable battery set 52 is connected electrically to the power output port 55 such that electrical power from the rechargeable battery set 52 is supplied to the load 6 via the power output port 55.

The control circuit 50 is disposed in the housing 51, and detects amount of the electrical power stored in the batteries 53.

The low-power indicating lamp 57 is mounted on the base body 511 of the housing 51, and is activated by the control circuit 50 to emit light when the control circuit 50 detects that the amount of the electrical power stored in the batteries 53 is at a low level.

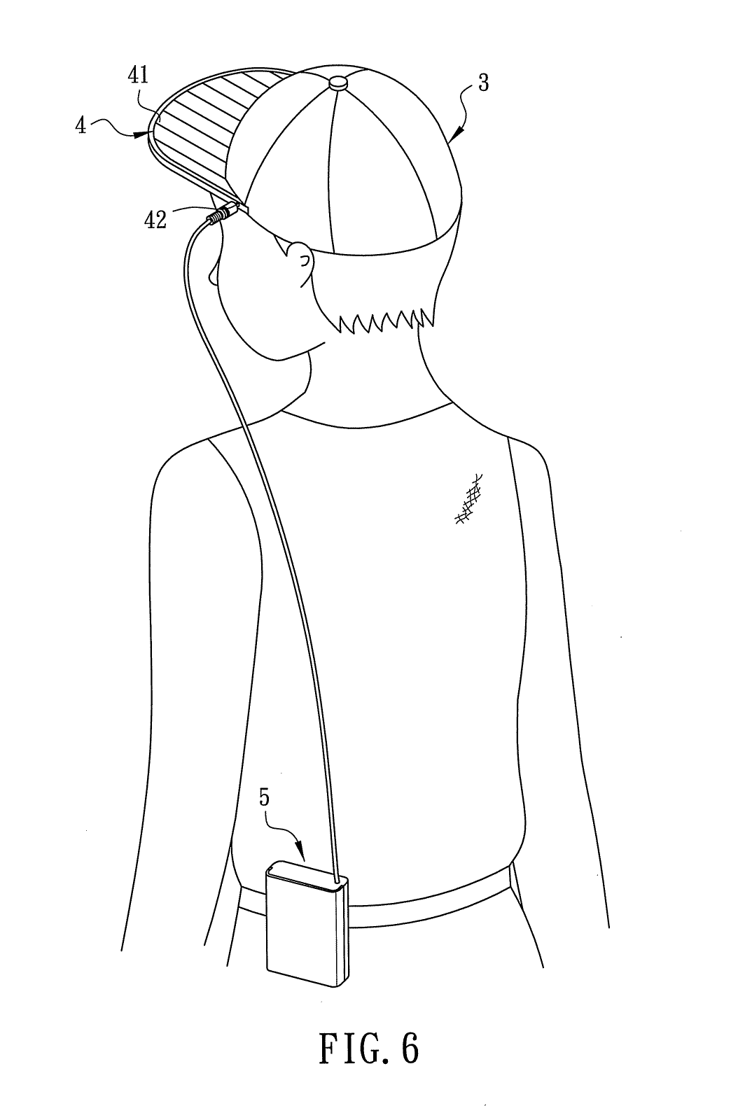

In use, the headgear member 3 is worn by the user, and the power supplying unit 5 is disposed in a pocket of an upper garment worn by the user, as shown in FIG. 5. Alternatively, the power supplying unit 5 can be hung on a belt worn by the user, as shown in FIG. 6.

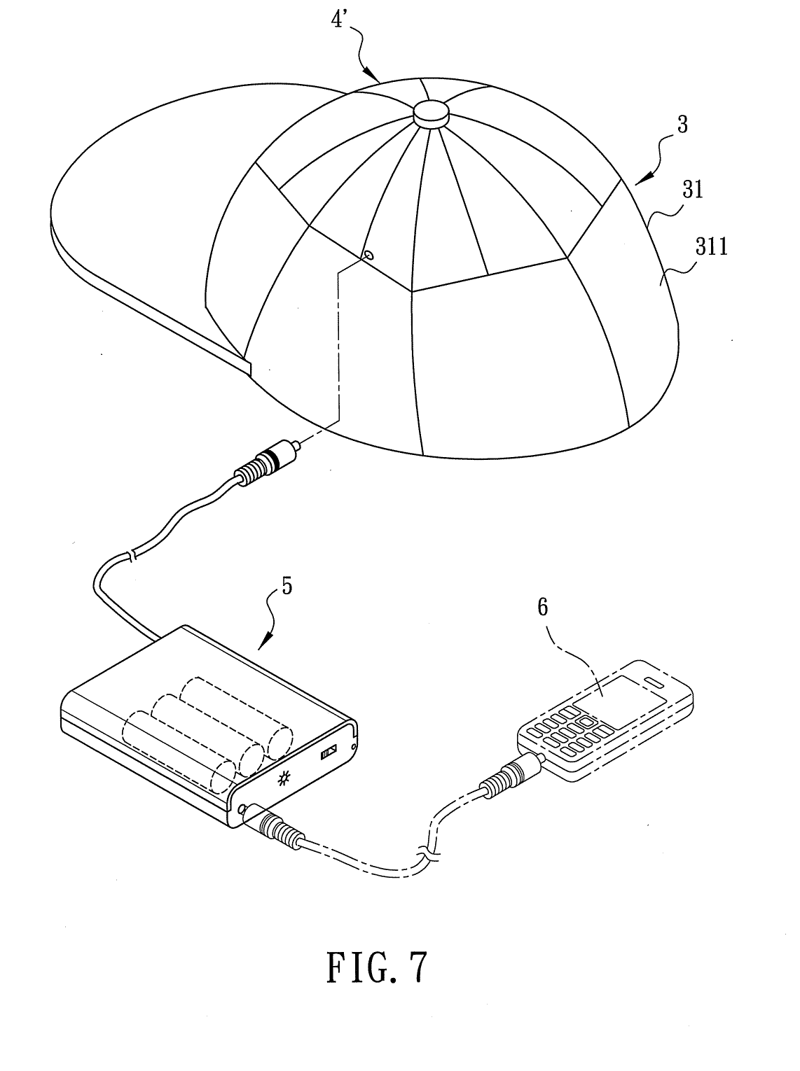

FIG. 7 illustrates the second preferred embodiment of a headgear assembly according to this invention, which is a modification of the first preferred embodiment. In this embodiment, the solar power collecting unit 4′ is mounted on an outer surface 311 of the cap body 31 of the headgear member 3.

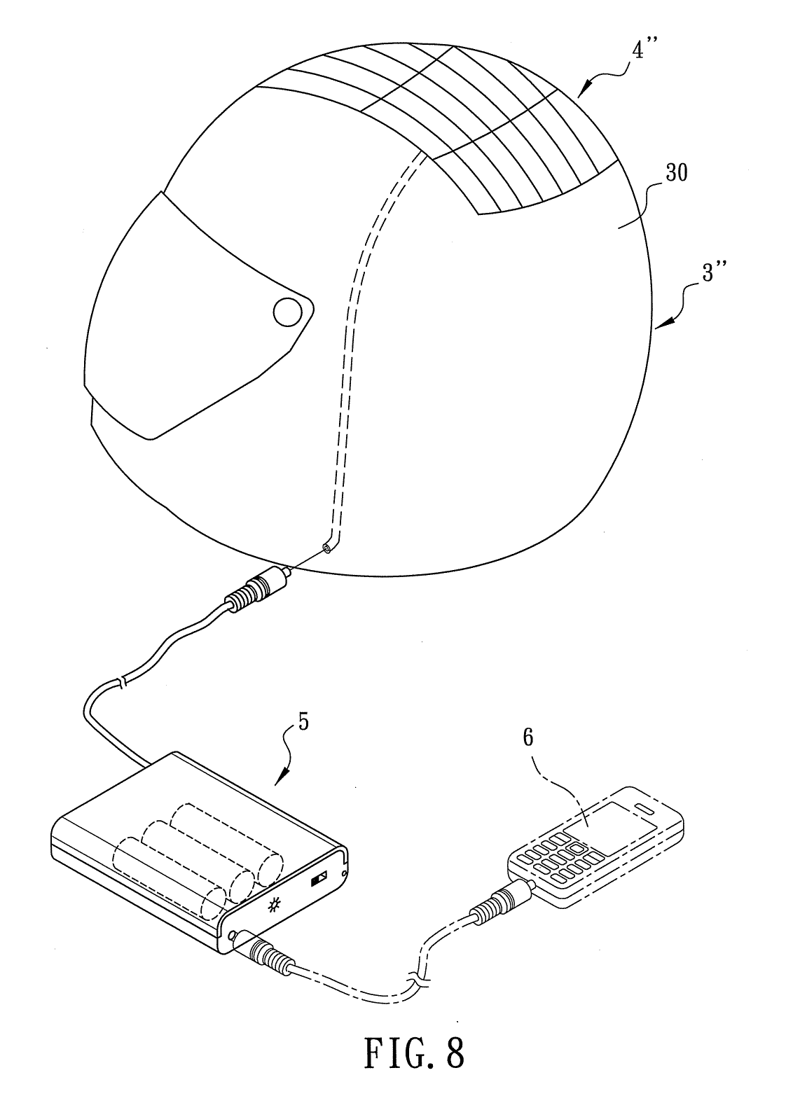

FIG. 8 illustrates the third preferred embodiment of a headgear assembly according to this invention, which is a modification of the first preferred embodiment. In this embodiment, the headgear member 3″ is in a form of a helmet, and has an outer surface 30 mounted with the solar power collecting unit 4″.

In sum, the headgear assembly of the present invention can be worn by the user during outdoor activities and can serve as a power supply for an external electronic device, thereby facilitating outdoor use.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A headgear assembly comprising:
a headgear member adapted to be worn by a user;
a solar power collecting unit mounted on said headgear member and adapted to convert solar power into electrical energy; and
a power supplying unit including
a housing configured with a battery-receiving space,
a rechargeable battery set disposed in said battery-receiving space in said housing and connected electrically and wiredly to said solar power collecting unit such that the electrical energy from said solar power collecting unit is used to charge said rechargeable battery set,
a power output port mounted on said housing and adapted to be connected electrically to a load, and
a power switch mounted on said housing, connected electrically between said rechargeable battery set and said power output port, and operable so as to switch between an OFF state, where said rechargeable battery set is disconnected electrically from said power output port, and an ON state, where said rechargeable battery set is connected electrically to said power output port such that electrical power from said rechargeable battery set is supplied to the load via said power output port.

2. The headgear assembly as claimed in claim 1, wherein said headgear member is in a form of a cap that includes a cap body adapted to be worn by the user, and a visor connected to and extending outwardly from a periphery of said cap body.

3. The headgear assembly as claimed in claim 2, wherein said visor has a top surface mounted with said solar power collecting unit.

4. The headgear assembly as claimed in claim 2, wherein said cap body has an outer surface mounted with said solar power collecting unit.

5. The headgear assembly as claimed in claim 1, wherein said headgear member is in a form of a helmet, and has an outer surface mounted with said solar power collecting unit.

6. The headgear assembly as claimed in claim 1, wherein said solar power collecting unit includes a solar power collecting plate, and said rechargeable battery set includes a cable unit connected electrically and separably to said solar power collecting plate.

7. The headgear assembly as claimed in claim 1, wherein said power supplying unit further includes a low-power indicating lamp mounted on said housing and activated to emit light when amount of the electrical power stored in said rechargeable battery set is at a low level.

8. The headgear assembly as claimed in claim 1, wherein said rechargeable battery set includes a battery selected from the group consisting of a lithium battery, a nickel-hydrogen battery, a nickel-cadmium battery and a carbon-hydrogen battery.
